(19) United States
(12) Patent Application Publication
(10) Pub. No.: US 2006/0276163 A1
(43) Pub. Date: Dec. 7, 2006

(54) Connection system base part and adapter part for connecting mobile radio terminals

(76) Inventors: Thomas Schlegel, Nurnberg (DE); Wolfgang Cullmann, Langenzenn (DE)

Correspondence Address: THE FIRM OF KARL F ROSS, 5676 RIVERDALE AVENUE, PO BOX 900, RIVERDALE (BRONX), NY, 10471-0900, US

(21) Appl. No.: 10/572,192

(22) PCT Filed: Sep. 8, 2004
(86) PCT No.: PCT/DE04/01999

§ 371 Date: Aug. 16, 2006

(30) Foreign Application Priority Data
Sep. 16, 2003 (DE) 203 14 317.5

(51) Int. Cl. H05K 11/02; H04B 1/06

(52) U.S. Cl. 455/345

(57) ABSTRACT

The invention relates to a connection device (1) which is used to connect mobile radio terminals (51, 52, 53) to an electronic system (2) arranged in a vehicle, and a base part (3) and an adapter part for said type of connection system. The connection system (1) comprises a base part (3) which is permanently fixed in the vehicle and one or several retaining parts (41, 42) for respectively receiving a mobile radio terminal (52, 52). The base part (3) comprises a first electric interface (11) which is connected to a signal processing device (2) arranged in the vehicle, said device performing at least partial functions of a handsfree device. The base part (3) also comprises a second mechanical and electrical interface (12) which is used to connect retaining parts (41, 42) in order to receive mobile radio terminals (51, 52), in addition to a communication device (5) for wireless communication with a mobile radio terminal (53) via a third interface (13). The communication device (5) is configured in such a manner that it communicates with the signal processing device (2) via a first interface (11) by means of a first protocol and it converts the first protocol into a third protocol in order to communicate with the mobile radio terminal (53) via a third interface (13).

The present invention relates to a connection system for connecting mobile radio terminals to electronics disposed in a motor vehicle, and to a base part and an adapter part for a connection system of this kind.

EP 1 119 160 A2, for example, describes a universal connection system for mobile radio terminals.

A hands-free system that can be installed in a vehicle comprises a universal, fixed system part and a replaceable system part. The universal system part has a power-supply unit, a microphone, and a loudspeaker, all of these being connected electrically to the power-supply unit, and a special cable. The cable has a first electrical connector for connecting it to the power supply unit and a second connector for connecting it to the vehicle antenna. The cable is also connected to a retaining plate that can be connected to the replaceable system part. The replaceable system part consists of a retaining part that serves to accommodate the mobile radio terminal, and incorporates electronics for matching the power supply between the power supply unit and the mobile radio terminal.

It is the objective of the present invention to improve the flexibility of a connection system used to connect mobile radio terminals to electronics disposed in a vehicle.

This objective has been achieved with a connection system for connecting mobile radio terminals to electronics that are arranged within a vehicle, which incorporates a base part for permanent installation within the vehicle and one or a plurality of retaining parts, each of which accommodates a mobile radio terminal, which can be connected to the base part by way of a second mechanical and electrical interface, and also incorporates an adapter part that incorporates the second mechanical and electrical interface for connecting the adapter part electrically and mechanically to the base part instead of to the retaining part, said retaining part incorporating a control device for converting a first, universal protocol into a second, terminal-specific protocol, the adapter part incorporating a communication device for wireless communication with a mobile radio terminal by way of a third interface, and being so equipped that it communicates through the second interface by means of the first, universal protocol. In order to communicate with the mobile radio terminal by way of the third interface, it converts the first protocol into a third protocol. This objective has also been achieved by an adapter part for a communications system, which serves to connect mobile radio terminals with electronics installed in a vehicle, the adapter part incorporating the second mechanical and electrical interface for mechanical and electrical connection to the base part of the connection system and the communication device. The objective has also been achieved by a base part of the communication system that incorporates a first electrical interface for connection to a signal-processing device arranged within the vehicle, which performs at least part functions of a hands-free device, which incorporates a second mechanical and electrical interface for the connection of retaining parts to accommodate mobile radio terminals, and that also incorporates a communication device for wireless communication with a mobile radio terminal by way of a third interface, the communication device being so configured that it communicates with the signal-processing unit through a first interface, by means of a first protocol, and converts the first protocol into the third protocol in order to communicate with the mobile radio terminal by way of a third interface.

The present invention entails a number of advantages. For example, it makes it possible to connect electronics installed permanently in a vehicle to a variety of mobile radio terminals at very little cost. Thus, it is possible to connect mobile radio terminals that have Bluetooth interfaces and with different proprietary, galvanic control interfaces to one and the same vehicle electronics system, without having to make any modifications to these electronics. In addition, this results in cost advantages during production and increases the user-friendliness of the connection system.

Advantageous developments of the invention are set out in the secondary claims.

Thus, it is, for example, expedient to equip a base part according to the present invention with a second mechanical and electrical interface that is suitable for connecting retaining parts for mobile radio terminals which have a control device for converting the first, universal protocol into a second terminal-specific protocol. This ensures the upward compatibility of the connection system and makes it possible to design the connection system for any other future mobile radio terminals.

In addition, it is also possible that the second mechanical and electrical interface of the base part be an interface for communication by means of one or a plurality of terminal-specific protocols. In this case, it is preferred that the communication device be so configured that it sends data to the signal-processing unit that triggers the signal-processing unit and/or permits the signal-processing unit to communicate with the communication device by means of the first protocol.

Additional advantages are obtained in that the base part has a selector circuit for selective connection to the first interface and the second interface, or the first interface with the communication device. Switching can take place automatically or it can be controlled manually. The selector circuit ensures that the vehicle electronics are always connected with the desired mobile radio terminal.

It is expedient that the first electrical interface be an interface for communication by means of the first, universal protocol. In this case, the base part can be configured in a simple and cost-effective manner.

Advantages from the standpoint of production technology can be achieved in that communication device consists of a plurality of electrical components that are arranged on a separate electrical connecting element, for example, a circuit board, the separate circuit board being connected through a plurality of contact elements to the main circuit board of the base part. The communication device is thus in the form of a “postage stamp” that can be attached very simply to a circuit board of the base part, of the signal-processing unit, or of the adapter part. This permits a particularly cost effective retrofitting of a connection system with the additional performance features achieved by the present invention. There are also cost advantages in the initial installation since, in order to achieve the increased range of performance, all that need be done is to attach the “postage stamp” to the location of the base part circuit board, the signal-processing unit, or the retaining part provided for this purpose.

In the case of an adapter part according to the present invention, additional advantages can be achieved in that the communication device ascertains whether or not the vehicle electronics communicate by way of the second interface with the first protocol and, if this is not the case, transmits data that trigger the vehicle electronics and/or permit the vehicle electronics to communicate with the communication device by means of the first protocol. This means that the adapter part can be used both in connection systems in which the retaining parts have a control device for converting the first, universal protocol into a second vehicle-specific protocol, and in connection systems in which the retaining part or a preceding signal processing unit communicates with the retaining part by way of an appropriate terminal-specific protocol, using previously established data or data downloaded from the retaining part. Thus, the adapter part is flexible enough that it can be used in a number of different connection systems.

In this regard, it is particularly advantageous that the adapter part have a housing that is in the form of a cover that covers the second electrical and mechanical interface. It thus performs a double function: first, it provides a visual and mechanical cover for the first interface for the event that this is not required, and second, it provides increased flexibility by making it possible to communicate with a further group of mobile radio terminals. These mobile radio terminals can, for example, remain in the user's pocket or in the trunk of the vehicle.

As an alternative to this, it is also possible to arrange one or a plurality of input and output devices on the adapter part and thereby replicate the user interface of the mobile radio terminal. This permits the customary operation of the mobile radio terminal even though the mobile radio terminal is not within the user's reach or sight.

The present invention will be described in greater detail below on the basis of a number of embodiments shown in the drawings appended hereto. These drawings show the following:

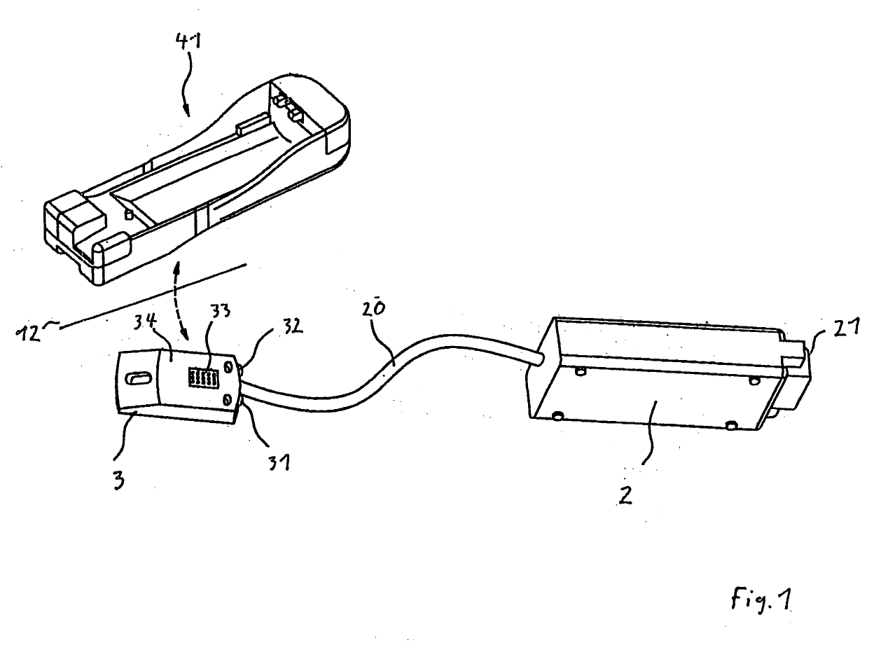

FIG. 1: a perspective view of a connection system with a base part, a signal-processing unit, and a retaining part according to the present invention;

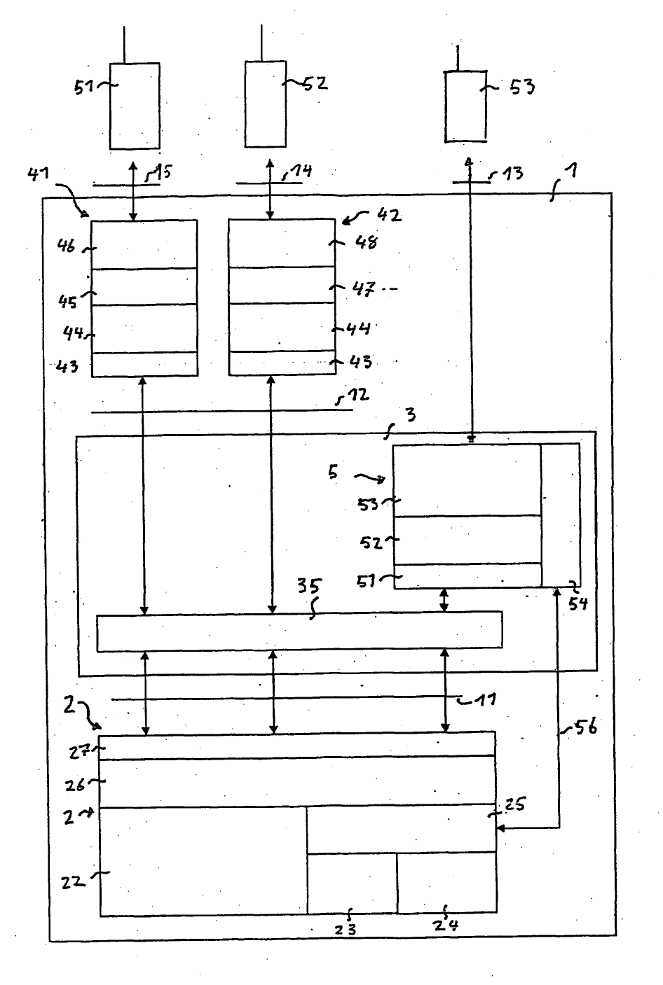

FIG. 2: a block circuit diagram of the connection system as shown in FIG. 1;

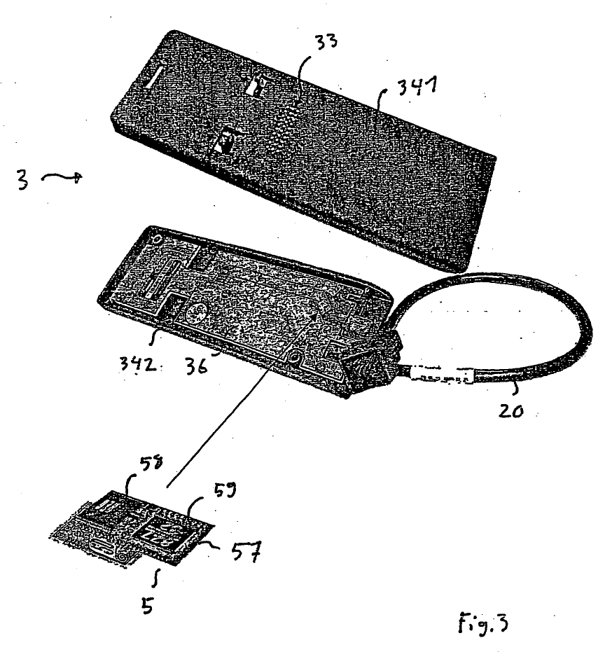

FIG. 3: an exploded view of the retaining part according to the present invention as shown in FIG. 1;

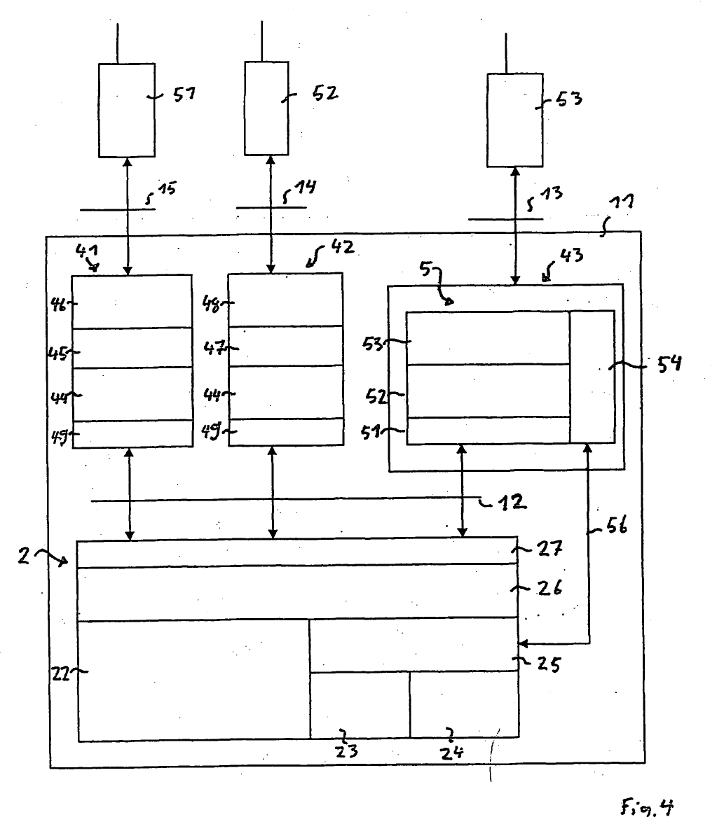

FIG. 4: a block circuit diagram of a connection system according to the present invention;

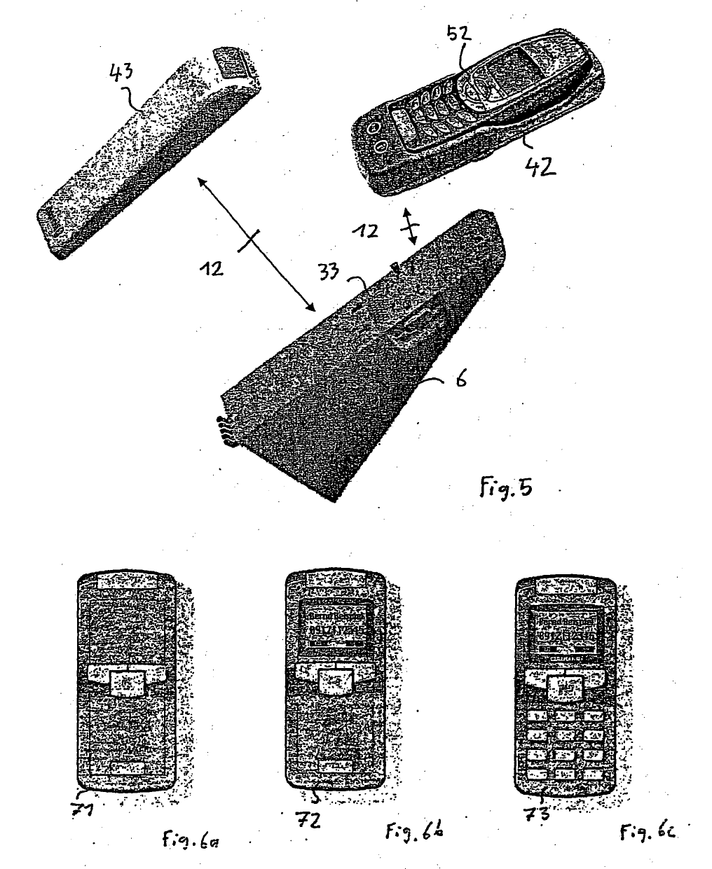

FIG. 5: a perspective view of the connection system according to the present invention shown in FIG. 4;

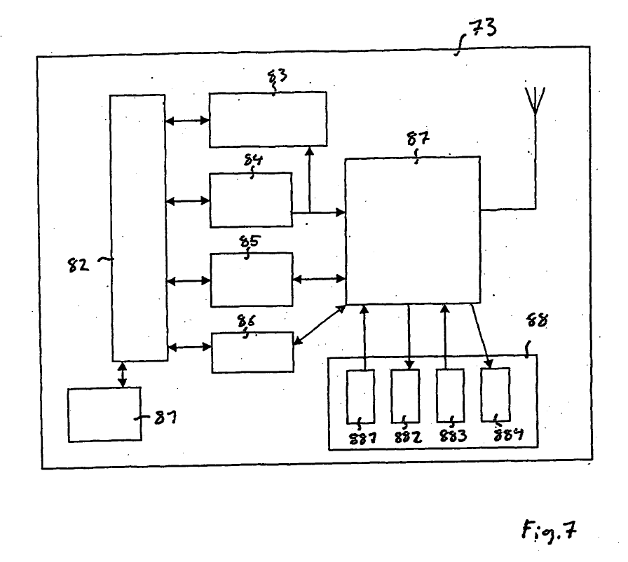

FIG. 6a to FIG. 6c: plan views of the adapter part according to the present invention;

FIG. 7: a block circuit diagram; of the adapter part according to the present invention.

FIG. 1 shows a plurality of components for a connection system used to connect a mobile radio terminal to a vehicle. FIG. 1 thus shows a retaining part 41, a base part 3, and a signal-processing unit 2.

The retaining part 41 is used to accommodate a special type of mobile radio terminal. At the front, the base part 41 has a recess that matches the external shape of this mobile radio terminal and, under certain circumstances, together with corresponding retaining, fixing, or locking means, this makes it possible to fix mobile radio terminals of this type in the retaining part 41 mechanically. In additional to this mechanical fixing, it is also possible that the retaining part 41 also incorporate electrical contacts that permit an electrical connection between the mobile radio terminal and the retaining part 41. Thus, the retaining part 41 incorporates an electrical plug that engages in a corresponding socket in the mobile radio terminal when the mobile radio terminal is introduced into the retaining part 41. It is also possible that the retaining part 41 incorporate not only one electrical plug but two or more plugs of this kind, one such plug serving to connect a mobile radio terminal to an external vehicle antenna while the second plug serves to create the galvanic connection with a control interfaces and/or a power-supply interface.

Both the mechanical interface, which permits the mechanical fixing of the mobile radio terminal, and the electrical interface that provides an electrical connection between the retaining part and the mobile radio terminal are configured according to the particular mobile radio terminal. The connection system also has additional retaining parts (not shown in FIG. 1) that are intended for other mobile radio terminals and accordingly implement another mechanical and/or electrical interface.

On, its underside the retaining part 41 has a second electrical and mechanical interface 12 that serves to connect the retaining part 41 electrically and mechanically to the base part 3. For example, it has an electrical contact element that is arranged as a counterpart for an electrical contact element 33 of the base part within the retaining part 41, and when the retaining part is being fixed on the base part 3 it works in conjunction with the contact element 33 to form an electrical connection between the retaining part and the base part. The second electrical and mechanical interface 12 is thus identical in all the retaining parts of the connection system, so that each of these retaining parts can be connected electrically and mechanically to the base part 3, which is thus universal.

It is preferred that the retaining part 41 or the base part 3 incorporate a locking mechanism that permits the rigid attachment of the retaining part 41 on the base part 3.

In addition, it is also possible that the retaining part 41 can be connected to the base part 3 by way of a cable that is fitted with a plug.

The base part 3 is installed permanently within the vehicle, preferably within the driver's reach or sight. The base part 3 consists of a housing 34 that incorporates recesses for the electrical contacts 33, and electrical switches 31 and 32. In addition, the base part 3 incorporates an electronic circuit as well as the electrical contacts 33 that are connected to the electronic circuit. The housing 31 can be installed permanently within the vehicle so that the base plate of the housing 34 incorporates recesses, for example, for bolting or screwing the base part to the vehicle. The switches 31 and 32 control functions that are performed by the electronics of the base part 3, of the signal-processing unit 2, of the retaining part 41, and/or of the mobile radio terminal.

The base part 3 is connected to the signal processing unit 2 by way of a cable 20.

The signal-processing unit 2 is similarly installed rigidly in the vehicle and consists of a housing and electronics that are arranged within this housing. It is preferred that these electronics perform the functions of a hands-free device. However, is also possible that these electronics only perform some or the functions of a hands-free device. In addition, it is also possible that the signal processing unit performs such functions as speech processing, speech recognition, and/or vehicle navigation The signal-processing unit 2 also has an electrical connector element 21 that serves to connect microphones or loudspeakers that are installed permanently in the vehicle, connection of a communications bus that is installed within the vehicle, or connection of the vehicle's other electronic devices.

The functional combination of the signals processing device 2, the base part 3, and the retaining parts 1 will now be explained on the basis of FIG. 2.

FIG. 2 shows the connection system 1 and mobile radio terminals 51, 52, and 53. The connection system 1 incorporates the signal processing unit 2, the base part 3, and a plurality of different retaining parts, of which retaining part 41 and a retaining part 42 are shown in FIG. 2. The signal-processing unit 2 is connected to the base part through an interface 11; the base part 3 is connected with the retaining parts 41 and 42 through the interface 12; and the retaining parts 41 and 42 are each connected to the mobile radio terminals 51 and 52 through terminal-specific interfaces 15 and 14.

According to a first embodiment of the present invention, both the signal processing unit 2 and the retaining parts 41 and 42 each have a microprocessor or microcontroller that performs functions within the framework of the communications between signal processing unit 2 and the mobile radio terminals 51 and 52.

From the functional standpoint, the signal processing unit 2 incorporates two communication devices 27 and 26 and a control unit 22. The retaining parts 41 and 42 incorporate communication devices 44, 46, 48, and 49 as well as control units 45 and 47. The functions of these communication devices and control units are performed by running a program code on the particular microprocessor or microcontroller in conjunction with the associated peripheral components.

The control unit 22 is formed from functions of a signal processing unit 2, which communicates with the mobile radio terminals 51 or 52 to fulfill its function. A function of this kind is, for example, a hands-free device with integrated speech recognition. In order to communicate with the terminals 51 or 52, the control unit 22 accesses the control unit 22 on the communication device 26, which in its turn accesses the communication device 27.

The communication device 27 performs functions that permit the exchange of data by way of the interface 11, using a transport protocol. The communication device 26 performs functions that permit communication by way of the interface 11, using a universal communications protocol that is structured on this transport protocol. In this instance, universal means that the protocol provides a set of commands and data telegrams that, on the one hand, is independent of the particular terminal-specific application program interface of the mobile radio terminals 51 and 52, and, on the other hand, is able t6 control these important functions of these varied terminals. Thus, this universal protocol can not be interpreted directly by the mobile radio terminals 51 and 52 but, however, on the other hand, it has sufficient semantic scope to be able to control all these varied mobile radio terminals given appropriate protocol conversion.

The communication devices 44 and 49 of the retaining parts 41 and 42 include the functions of the communication devices 27 or 26, respectively, so that communication is possible between the control units 22 and 45 and 47, respectively, using a universal protocol. The communication devices 46 and 48 provide functions that permit communication with the terminals 51 or 52, respectively, in each case by way of a terminal-specific protocol. The control units 45 and 47 perform a protocol conversion between the particular terminal-specific protocol and the universal protocol.

From the functional standpoint, the base part 3 incorporates a selector circuit 45 and a communication device 5. The communication device 5 is preferably formed from a microcontroller or microprocessor with associated peripheral elements.

From the functional standpoint, the communication device 5 incorporates three communication devices 51, 52, and 53, as well as a control unit 54. The communication devices 51 and 52 perform the functions of the communication devices 27 or 26, respectively, and accordingly permit communication between the control unit 22 and the communication unit 53 by way of the universal protocol. The communication device 53 provides functions that permit wireless communication with the mobile radio terminal 53 through an interface 13. Preferably, the interface 13 is a radio interface. However, is also possible that communication be based on ultrasound or infrared. In addition, communication is, effected through the interface 13, preferably by means of the Bluetooth protocol, so that the communication device 53 performs a conversion between universal protocol and the Bluetooth protocol.

The control unit 54 is an optional expansion of the communication device 5. The control unit 54 checks whether or not the signal processing unit 2 communicates through the interface 11 by means of the universal protocol. In the event that this is not the case, it passes data 56 to the signal processing unit 2, said data then triggering the signal processing unit 2 and/or permitting the signal processing unit 2 to communicate with the communication device 5 through the interface 11, using the universal protocol. Because of this, a base part 3 can be used in various types of communications systems with variously configured retaining parts and signal processing units.

This will now be explained on the basis of two additional embodiments of the present invention.

On the one hand, it is possible that the signal-processing unit 2 does not communicate with the mobile radio terminals 51 and 52 by means of the universal protocol, but rather by means of the particular terminal specific protocol. Thus, the signal processing unit 2 uses different protocols for communication through the interface 11, depending on which terminal and which retaining part is connected to the base part 3. Selection of the particular, correct protocol is effected, for example, by means of data that is sent from the retaining parts 41 or 42 to control unit 25 of the signal processing unit 2.

According to a first, additional embodiment, in the event that a signal processing unit 2 of this type is used, the control unit 54 sends a command that refers to a specific protocol that is available in a signal processing unit 2 to a control unit 25 of the signal processing unit 2. Subsequently, this protocol is used by the signal processing unit 2 in order to communicate through the interface 11.

According to a second, additional embodiment, the control unit 54 passes software and data to the control unit 25, and this software and data first make it possible for the signal-processing unit 2 to communicate through the interface 11 by means of the protocol that is awaited by the communication device 5.

FIG. 2 shows two control units 23 and 24, the control unit 23 containing the signal processing functions for the implementation of the first additional embodiment, and the control unit 24 containing the signal processing functions for implementing the second additional embodiment.

The selector circuit 35 provides for the selective connection of the interface 11 with the interface 12, or the interface 11 with the communication device 5. Switching can be effected by manual operation of a switch disposed in the base part or it can be effected automatically. Thus, it is, for example, possible that the base part 3 incorporate a contact switch that recognizes whether or not the retaining part is on the base part 3. If this is the case, the interface 11 is connected to the interface 12, and if this is not the case, then the interface 11 is connected to the communication device 5.

FIG. 3 shows an additional embodiment of the base part 3.

Here, the base part 3 has a housing upper section 341 and the housing lower section 342. Within the housing there is a circuit board 36 that is connected electrically to the connection cable 20. The circuit board 36 is prepared to accommodate the communication device 5. A plurality of electrical contact points is provided, and the connection device 5 can be set on these.

As is shown in FIG. 3, the communication device 5 consists in this instance of an electrical connection element 57 on which a plurality of components 48 and 59 is installed. In the case of the electrical connection element 55, it is preferred that this be a multilayer circuit board that is provided on one side with electrical contact points for electrical connection to the circuit board 36.

Depending on the way it is populated, the base part 3 can be provided in a very simple way with the communication device 5, or not be so provided.

FIG. 4 shows the operation of a connection system 11 according to the present invention, which is used to connect mobile radio terminals 51, 52, and 53 to electronics installed in a vehicle.

FIG. 4 shows the connection system 11, the base part 3, the retaining parts 41 and 42, as well as an adapter part 43. Between the retaining part 41 and 42 and the adapter part 43 on one side, and the signal processing unit 2 on the other there is a base part (not shown in FIG. 4) that has the electrical interface 12 on both sides, and thereby passes signals between the signal processing unit 2 and retaining part 41, retaining part 42 and adapter part 43, respectively.

The adapter part 43 incorporates the same electrical and mechanical interface 12 as the retaining parts 41 and 42, so that the adapter part can be connected to the base part in the same way as the retaining parts 41 and 42. In addition, the adapter part 43 incorporates the communication device 5.

The signal processing unit 2, the retaining parts 41 and 42, as well as the mobile radio terminals 51, 52, 53, are configured here as shown in FIG. 1 and FIG. 2. The base part is configured in the same way as the base part 3 in FIG. 1 and FIG. 2, but with the difference that the base part has neither communication device 5 nor the selector circuit 35.

It is, however, also possible that some of all of the functions of the signal processing unit 2 can be transferred from the signal-processing unit 2 to the base part.

FIG. 5 shows a preferred embodiment of the adapter part 43 as well as of the base part that is used for the connection system 11.

FIG. 5 shows a base part 6 that can be connected through the electrical and mechanical interface 12 to the adapter part 43 or to a retainer part 42 that has the mobile radio terminal 52 installed in it. As is shown in FIG. 5, the adapter part 43 is, in this instance, in the form of a cap that covers the mechanical and electrical interface 12 of the base part 6. The lower part of the housing of the adapter part 43 has recesses that permit it to snap together with the raster elements shown in FIG. 5. In addition, the lower section of the housing incorporates an electrical contact that is arranged as a counter piece to the contact element 33 of the base part 6 that the shown in FIG. 5.

It is advantageous if the adapter part 43 has a housing that is shaped so as to cover of the base area of the base part 6 in a positive fit, thereby hiding the interface 12 completely. In addition, the adapter part can incorporate one or plurality of LEDs as status indicators.

FIG. 6a, FIG. 6b, and FIG. 6c show other possible embodiment of an adapter part for use in the connection system 11.

An adapter part 73 incorporates a plurality of input and output devices that form the user interface of the mobile radio terminal 53, so that the complete operations spectrum of this mobile radio terminal is available to the user without the mobile radio terminal having to be within the driver's reach or sight.

An adapter part 72 has a reduced user interface that essentially incorporates an indicator device and keys for varying the loudspeaker volume, for temporary interruption of the communications connection, and to break off/initiate a communications connection.

In contrast to the adapter part 72, an adapter part 71 has no LCD display, but simply an LED to indicate status.

The exact structure of the adapter part 73 will now be explained on the basis of FIG. 7.

FIG. 7 shows the adapter part 73 with an electrical connection element 82, a connectors socket for a cables 81, an EPROM 83, the power supply unit 34, a driver 85 for the signaling lines, an adapter circuit for adapting the audio signals, a microcontroller 87, and an input-output unit 88 that has a display 884, a keyboard 883, an LED 882, and an operating switch 881. The microcontroller 87 is also connected to an HF circuit that is, in its turn, provided with an antenna to enable it to communicate through the radio interface 13. The microcontroller 87 performs the functions of the communication device 5, as is described in FIG. 2 and FIG. 4.

1. Adapter part (43, 71, 72, 73, for a connection system (11) that that serves to connect mobile radio terminals (51, 52, 53) with electronics (2) installed in a vehicle, the connecting system (1) incorporating a base part (3) for permanent installation in the vehicle and one or a plurality of retaining parts (41, 42), each of which accommodates a mobile radio terminal (51, 52) that can be connected through a second mechanical and electrical interface (12) to the base part (3), characterized in that the adapter part (43, 71, 72, 73) incorporates: the second mechanical and electrical interface (12) for electrical and mechanical connection to the base part (3) of the connection system (11), the second mechanical and electrical interface being an interface for the connection of retaining parts for mobile radio terminals, that incorporates a control device (45, 47) for communication through the second interface by means of a first, universal interface and for converting the first, universal protocol into a second, terminal-specific protocol; and in that the adapter part (43) has a communication device (6) for wireless communication with a mobile radio terminal (53) through a third interface (13) and the communication device (5) parentheses is so configured that it communicates through the second interface (12) by means of a first, universal protocol and in order to communicate with the mobile radio terminal through the third interface (13) it converts the first protocol into a third protocol.

2. Adapter part (43) as defined in claim 1, characterized in that the communication device (5) is so configured that it transmits data (56) through the second interface (12) that triggers the vehicle electronics (2) and/or enables the vehicle electronics (2) to communicate with the communication device (5) by means of the first protocol.

3. Adapter part (43) as defined in claim 2, characterized in that the communication device (5) is so configured that it determines whether or not the vehicle electronics (2) communicate through the second interface (12) with the first protocol and, if this is not the case, it transmits the data (56).

4. Adapter part (43) as defined in one of the claims 1 to 3, characterized in that the adapter part (43) has a housing that is in the form of a cover that covers the base part (6) in the area of the second electrical and mechanical interface (12).

5. Adapter part (72, 73) as defined in one of the preceding claims, characterized in that the adapter part (72, 73) incorporates an indicator device.

6. Adapter part (73) as defined in one of the preceding claims, characterized in that, the adapter part (73) incorporates a keyboard

7. Adapter part (73) as defined in one of the preceding claims, characterized in that the adapter part (73) incorporates one or a plurality of input and output devices for replicating the user interface of the mobile radio terminal (53), with which the adapter part (73) communicates through the third interface (13).

8. Connection system (11) to connect mobile radio terminals (51, 52, 53) with electronics (2) installed in a vehicle, the connection system (11) incorporating a base part (3) for permanent installation in the vehicle and one or a plurality of retaining parts (41, 42), each of which accommodates a mobile radio terminal (51, 52), which can be connected to the base part (3) through a second mechanical and electrical interface (12), characterized in that the retaining part (41, 42) incorporates a control device for communication through the second interface by means of a first, universal protocol and for converting the first, universal protocol into a second, terminal-specific protocol; in that the connection system (11) also incorporates an adapter part (43, 71, 72, 73) that incorporates the second mechanical and electrical interface (12) for electrical and mechanical connection of the adapter part (43, 71, 72, 73) to the base part (6) of the connection system (11) in place of the retaining part (41, 42); and in that the adapter part (43, 71, 72, 73) incorporates a communication device (5) for wireless communication with a mobile radio terminal (53) through a third interface (13), and the communication device (5) is so configured that it communicates through the second interface (12) by means of the first, universal protocol and in order to communicate with the mobile radio terminal (53) through the third interface (13) it converts the first protocol into a third protocol.

9. Connection system (11) as defined in claim 8, characterized in that the base part (6) has a first electrical interface for connection to a signal processing unit that is installed within the vehicle and performs at least some of the functions of a hands-free device.

10. Base part (3) as defined in claim 9, characterized in that the second mechanical and electrical interface (12) of the base part (3) is an interface for communication by means of one or a plurality of terminal-specific protocols; and in that the communication device (5) is so configured that that it transmits data to the signal-processing unit that triggers the signal-processing unit (2) and/or enables the signal-processing unit (2) to communicate with the communication device (5) by means of the first protocol.

11. Connection system as defined in claim 9 or claim 10, characterized in that the first electrical interface (11) is an interface for communication by means of the first, universal protocol.

12. Connection system (11) as defined in one of the claims 8 to 11, characterized in that the third interface (13) is a radio interface and the third protocol is preferably a Bluetooth protocol.
